(19) United States
(12) Patent Application Publication
(10) Pub. No.: US 2010/0102809 A1
(43) Pub. Date: Apr. 29, 2010

(54) DIFFERENTIAL GRADIOMETRIC MAGNETOMETER, SYSTEM AND METHOD OF USE

(76) Inventor: Wayne A. May, Las Vegas, NV (US)

Correspondence Address: GREENBERG TRAURIG (LV), 3773 HOWARD HUGHES PARKWAY, Suite 400 North, LAS VEGAS, NV, 89169, US

(21) Appl. No.: 12/536,404

(22) Filed: Aug. 5, 2009

Related U.S. Application Data
(60) Provisional application No. 61/086,207, filed on Aug. 5, 2008.

(51) Int. Cl. G01R 33/02; G01R 33/00

(52) U.S. Cl. 324/244; 324/260

(57) ABSTRACT

A three-dimensional real-time differential gradiometric magnetometer (DGM) array, system and method of use. The DGM exploits differential and gradiometric parametrics of an induced magnetic field anomaly surrounding an object interacting with an applied magnetic field. The DGM integrates differential magnetic field measurement with gradiometric magnetic field measurement into a single system. The DGM detects, locates and maps objects, while simultaneously measuring the distance between the DGM detection array and the object, axial orientation, apparent magnetic mass and magnetic moment. The DGM employs a signal processing technique to nullify source noise from the earth's magnetic field, external radio frequency transmissions and electromagnetic noise. A linear geometric architecture comprising a plurality of magnetometers forming the array enables the DGM to collect information directly in the spatial domain. The DGM is capable of capturing the complete field anomaly contour in three dimensions while the array traverses over, under or adjacent to an object.

### CROSS-REFERENCE

This application claims the benefit of U.S. Provisional Patent Application No. 61/086,207 filed Aug. 5, 2008.

### FIELD OF THE INVENTION

The embodiments of the present invention relate to a device and system for locating desired objects by sensing magnetic field interruptions and a method of using the device.

### BACKGROUND

Magnetometry has a long history of being useful for searching and finding things, especially if buried underground or submerged underwater. The types of items investigated by magnetometry are many and diverse, such as by example but certainly not limited to unexploded ordinances (UXOs), land and marine mines, submarine vessels, improvised explosive devices (IEDs), articles of archeological interest, geophysical features related to oil or mineral exploration, etc. Searching for, detecting and locating objects necessarily requires a survey of some prospect area. Conventional magnetometers and magnetometer systems accomplish such surveys by taking sample magnetic field measurements as the instrument and/or sensor(s) traverse along multiple paths, usually a series of parallel lines forming a serpentine. These sample data are logged or otherwise recorded in series, one data point after another, in the time domain. In some cases, the position or location of the instrument or sensor(s) is recorded in correlation to the sample data points, and used later to construct a survey map, that is, useful information in the spatial domain. Consequently, the conventional systems collect large data sets that require computer software manipulation to transform time domain data into meaningful information in the spatial domain, namely the object's location on a survey map or reference grid. This is true regardless of the field parameter being measured, e.g., scalar, vector, gradient or gradient rate change flux density, and regardless of the field sensor employed by the magnetometer, e.g. one, two or three axis vector type fluxgate, magnetodiode, Hall effect, magnetoresistive, magnetoinductive or spin tunnel junction devices, and/or by so called total field sensors such as proton cesium, or Overhauser devices.

### SUMMARY

In the field of magnetometry, the term magnetometer is often used interchangeably to denote an entire system or a single magnetic field sensing device. When referring to a single device, the term magnetometer is usually reserved for scalar devices (total field). However, there are counter examples in research literature and product brochures. The term sensor is exclusively used in reference to a single magnetic field sensing device, usually a vector type sensor. The term magnetometer and sensor are used interchangeably in this disclosure to denote a vector or scalar type device. The term magnetometer is also used in this disclosure to denote a complete system.

The detection array architecture and certain digital signal processing techniques represent the heart of the DGM instrument. The array is a network of a plurality of individual magnetic sensors or complete magnetometers arranged in a linear geometric pattern. For example, the array may comprise a series of evenly spaced sensors mounted within a simple carbon fiber tube. The practical upper and lower limit for array length is very broad, ranging from micrometer through kilometer scale. In one embodiment, the minimum number of individual sensors required by the DGM array is three. However, the upper limit is only constrained by engineering considerations. For example, an array one kilometer long may employ one thousand sensors evenly spaced at 1 meter intervals. Any type or kind of magnetic sensor or meter may be used in the array, such type or kind being appropriate for the application or task. The resolution of the sensors or meters employed in the array can be any value appropriate for the magnetometry objective.

The embodiments of the present invention teach a design and method whereby magnetic field information is collected directly in the spatial domain as the DGM array is traversed over, under or next to an object. It has this capability because the array is a linear arrangement of a plurality of magnetic field sensors that span both sides of the field anomaly as well as through it, thus measuring the background earth field and the induced field surrounding the object at the same time. The size of the induced field surrounding an object interacting with an applied field may be defined by the resolution of the instrument measuring it, or by some signal to noise ratio limit. The DGM array length can be designed to encompass the induced magnetic field surrounding most any object generally subject to magnetometry. For example, a 3 meter long array with a resolution of 1 ηT (one nanotesla=10⁻⁹ tesla, a unit of flux density) can encompass the induced field surrounding any object the size of a hand gun. A 6 meter long array operating at 0.5 ηT resolution would be sufficient for any land mine.

Depending on local magnetic field conditions, a digital signal processing algorithm chooses one sensor in the array as a reference. The output of this reference sensor is subtracted from the output of the remaining sensors, thus generating a series of differential measures regularly distributed along the length of the array. All differential measurements are taken at the same point in time. Since the physical characteristics of induced field anomalies are well known and common to all such fields, information about the shape, magnitude and gradient of the field anomaly can be correlated to the locations of the sensors in the array. This provides a means to present information to the operator in real time because data is collected directly in the spatial domain, at one point in time. Collecting information in this way translates to low computational requirements. There is no need for computer software data reconstruction as required by conventional systems.

In addition to the differential measurements made by the magnetometers in the DGM array, field gradient data can be also be extracted. Since the distance between each of the sensors along the array is fixed and known, field gradient information distributed at correlated points across the entire cross section of the field anomaly's prolate spheroid can be determined. When extracting gradient information, the difference between each sensor output and its immediate neighbor is measured. These scalar magnitudes are divided by the fixed distance between each sensor, thereby extracting vector gradiometric data that are also distributed at correlated locations along the array length. This design, coupled with a dual modus technique for output data processing, enables the array to function in both the differential and gradiometric mode simultaneously. Having simultaneous scalar differential and vector gradient information about the induced magnetic field surrounding an object allows solutions to be computed regarding the object's location in the x-y horizontal or map plane as well as along the z-axis or vertical axis, thus locating it in three dimensional space. Each time a sample measurement is taken by the array, a complete cross-sectional profile of the object's induced field is captured in vector quantity (data contain both direction and magnitude information). Consequently, as the array traverses over, under or next to an object being inspected, a series of contiguous cross-sectional profiles is collected spanning through the field anomaly at regular intervals in the direction of the traverse. These cross-sectional slices are then compiled to reveal the object's complete three-dimensional field contour. Thus, objects can be detected, located and mapped as the survey proceeds, not at some later time or date as with conventional systems.

There are several important distinctions to be made between conventional systems and the embodiments of the present invention with regard to mapping a survey area. Conventional systems are unable to generate meaningful survey maps in real time, even if streaming data are recorded and correlated to instrument location at the same time as they are collected. Whether scalar, vector, total field, gradien, or rate change gradient information is measured, it is done at one point in space for each data point recorded or mapped along a search line or path. Depending on the sample rate and search velocity of the instrument, mapping streamed data as it is collected produces a series of data points at regular distance intervals along a particular search line. The induced magnetic field surrounding an object interacting with an applied field has a physical size, shape and orientation. Since the search line may transect this field at any location relative to the object, i.e., across one edge, over the middle, etc., a complete picture of field size, shape and orientation cannot be known until data from a number of search lines sufficient to encompass the entire field are compiled. Only then can the object's location be determined. There is an important difference between recording data in real time, and actually locating and mapping an object in real time. Since the embodiments of the present invention can capture a complete cross-sectional profile of the induced field, the entire field contour is mapped as the traverse occurs, field size, shape, and orientation are imaged, and the object is located and mapped in real time.

Further, conventional systems produce survey maps that are two dimensional. When initially generated, these maps only contain location information in the x-y horizontal or projection map plane. If detection distance or depth information is not obtained or included in map generation, the survey map contains a location offset error. Offset is the horizontal distance between the maximum magnitude of an object's induced field as observed, and the actual location of the object's magnetic center of mass. This observed maximum magnitude, representing an extremum, occurs at the intersection of the dipole field axis on either side of the object, coaxial with the earth field vector wherein the object always lies along this line at some distance from the magnetometer. Since this axis line is inclined at some angle corresponding to the earth field vector inclination, the object is not directly below the extremum. Offset is only zero at the magnetic poles where the earth field vector is 90° up or down, and along the magnetic equator, where it is 0° North. For all other locations on the planet, the offset distance is a trigonometric function of the inclination angle of the earth field vector and the distance between the magnetometer and the object. For large detection distances such as deeply buried or submerged objects, and at middle geographic latitudes where the earth field vector is near 45°, the offset distance can be many times the diameter of the object being inspected. In the case of two dimensional survey maps generated by conventional systems, an object actually lies North or South of the location indicated by the field contour extremum. Persons not skilled in the art of magnetometry may not be aware of this geometry, in which case an offset error could prove significant, such as interpreting a survey map of land mines for example. In contrast, the embodiments of the present invention comprise of an array capable of operating in the differential and gradiometric modes simultaneously. This enables the system to measure contiguous cross-sectional profiles of the object's induced field as well as detection distance, that is, a three-dimensional data set is collected. Since the inclination of the earth field vector is known, a simple trigonometric computation can resolve the offset distance, and the object can be correctly located on the survey map. Consequently, the offset error of the DGM system is always zero regardless of the instrument's geographic location.

The linear geometric architecture and the use of a plurality of sensors in the array enable the DGM to make differential field measurements. Notwithstanding the fact that a traditional gradiometric magnetometer (sometimes called a gradiometer) makes a differential field measure by subtracting the output of one meter from its companion, an important distinction is to be made between this technique and the differential measurement technique of the embodiments of the present invention. By means of a digital signal processing algorithm, the output of one field sensor in the DGM array is subtracted from the output of all remaining sensors. These measurements are scalar magnitudes in contrast to the vector measure made by traditional gradiometers. Further, since there are a plurality of these differential scalar field measurements taken over the length of the array, and since they are correlated to the physical location of the sensors in the array, a complete contiguous cross-sectional scalar contour of the object's induced field is captured directly in the spatial domain. This is in contrast to conventional magnetometers that collect information in the time domain, from a single point in the object's induced field.

The same distinction exists between the gradiometric measurement technique of the embodiments of the present invention and conventional magnetometers. Instead of using the output signal from a single sensor in the array as a reference operand as with the array's differential measurements, a second digital signal processing algorithm subtracts the output of each sensor in the array from that of its immediate neighbor, then divides this scalar magnitude by the fixed distance between each sensor, thereby extracting a plurality of gradient vector data distributed along the array and correlated to the positions of the sensors in the array. These vector data constitute a contiguous cross-sectional gradiometric contour of the object's induced magnetic field, capturing it directly in the spatial domain in real time. This is in contrast to conventional magnetometers that collect similar information in the time domain, from a single point in the object's induced field.

The earth's magnetic field is dynamic and heterogeneous. It varies temporally in both magnitude and direction on scales that range from microseconds to millennia, and spatially from meters to hemispheric proportions (geomagnetic and secular discontinuities). Temporal variation represents source noise to survey, surveillance and inspection magnetometry when its period is comparable to instrument sample rate, and when its magnitude equals or exceeds instrument resolution. For traditional magnetometers, this source or background noise plays a degrading role in the relationship between signal-to-noise ratio and effective instrument resolution. If a magnetometer's measurement resolution is 1 ηT, and the earth's magnetic field varies by +/−3 ηT over a period near or less than the sample rate of the instrument, a 1 ηT signal may be lost in the noise, and the object would not be detectable. Conventional systems routinely employ various digital signal processing and/or software data manipulation techniques as a means to mitigate source noise. While these various circuit and software techniques are effective in mitigating source noise, they do not completely eliminate it, nor do they bring the signal to source noise ratio anywhere near unity when correlated to the instrument's resolution at any given sample rate. In addition, these source-noise mitigation/management techniques require circuits, firmware and/or software additional to the magnetometer system hardware/software itself. In many cases this can be complex and power consumptive, important issues for portable operation required for area surveys. This problem is exacerbated by conventional magnetometers or sensors that require calibrated and/or extremely precise field measurements. In fact, detection and location information is contained in the difference between the ambient earth field and the dipole field anomaly generated by an object. A calibrated measurement is not required to detect, locate or map an object. As previously explained, an innovative signal processing technique enables any one sensor in the array to act as a reference for the earth field. The output of this one sensor is subtracted from the output of the remaining sensors in the array, thus providing a differential measurement of the object's cross sectional field profile relative to the earth's field. Since all of the sensors in the array respond to changes in the local magnetic field in concert, at the same time and by the same output magnitude, with differential measurement, the problem of signal-to-noise ratio is preempted to near unity, and the DGM array is virtually immune to source noise at any instrument resolution or sample rate. In addition, this same technique enables the DGM array to be immune to interference from electromagnetic energy such as radio frequency radiation from man-made or natural sources (sun spot or coronal discharge for example).

Since the embodiments of the present invention do not require a calibrated field measure in order to detect, locate or map an object's location, instrument calibration is never required. This feature greatly reduces circuit and software complexity, operational requirements and maintenance over conventional systems.

In the case where a magnetometer is stationary and the object of interest is moving into or out of close proximity relative thereto, the embodiments of the present invention offer certain other advantages. In terms of equipotential flux density field lines, a useful construct for characterizing the induced field surrounding an object, the shape of the field is a prolate spheroid having its major axis parallel to, and coaxial with, the earth's total field vector (or with the total field vector of a man-applied field). In this situation, conventional systems are only capable of collecting scalar, vector or gradient information along a single line transecting the field contour as it passes the magnetic sensor(s). Consequently, conventional systems collect information in the time domain, one data point after another, as a function of the instrument's sample rate and the relative velocity of the passing object. The DGM array can be sized to transect the object's entire field contour extending completely through and beyond either side. For example, a 6 meter long array operating with a resolution of 0.5 ηT encompasses the induced field surrounding any hand-held or concealed weapon, including what is known as a suicide bomb vest. So in contrast to conventional systems, as an object passes the DGM array, the DGM collects field information through a contiguous plane constituting a cross section, instead of a single line constituting a thread. This means that the embodiments of the present invention collect magnetic field information directly in the spatial domain in the form of contiguous cross-sectional slices. Since these data are spatially differentiated in real time, as well as correlated to the known location of the magnetic sensors or meters along the array length, the cross-sectional slices can be compiled in real time, thus generating a full three-dimensional image of the object's field contour as it moves near or past the array. In this case, it is not the intention to generate a survey map, but rather a three-dimensional image, which for the embodiments of the present invention, can be presented to the operator via a display and accompanied by additional information about the object itself, such as apparent mass, range, magnetic moment and field orientation. The embodiments of the present invention are useful for detecting, tracking, and imaging vehicle or pedestrian traffic or other moving objects of interest. For example, if the DGM array were buried below or suspended above a pedestrian chokepoint, persons walking over or under the array could be surveiled for concealed weapons such as hand guns, grenades, suicide bomb vests, etc. In the case of an industrial application, the moving object, a machine part for example, could be detected for the purpose of process staging, timing, counting, or otherwise inspecting for defects, correct size (mass), etc.

There are certain other advantages the embodiments of the present invention offer over that of conventional systems regarding the relationship between spatial resolution and sample rate. Spatial resolution refers to the minimum distance an instrument can determine position along any orientation axis, viz. in the x-y horizontal or map projection plane, and/or the z-axis representing vertical distance or depth. Spatial resolution also refers to the minimum distance two objects in close proximity can be resolved. For example, if the spatial resolution of a magnetometer is 1 meter, then an object's center of magnetic mass can be located within a circular area 1 meter in diameter, representing a maximum position error of 50 centimeters, viz. half way between two data points on either side of the object. Sample rate refers to the number of field measurements or other measurements taken during a given period, usually expressed as samples per second (S/sec) or sometimes frequency (Hz), both having the same meaning and numerically equal. Since conventional systems collect information in the time domain, spatial resolution is a function of the sample rate and relative velocity between the instrument and the object under inspection. For example, if an instrument's sample rate were 1 S/sec, and its relative velocity were 1 meter/sec, its effective spatial resolution would be 1 meter. This translates into a maximum position error of 50 centimeters should the two data points detecting the object happen to fall equal distance on either side of the object. Interpolating these data as a means to resolve a more refined position is not possible in the absence of detection distance and apparent magnetic mass information. In the absence of these measures, the spatial rate change or slope of the field contour cannot be known. For example, a small object very close to a magnetometer presents a field profile with a very steep magnitude versus distance slope, i.e. a magnitude profile with a sharp or peaked shape. A larger object or the same object at a greater distance presents a field contour with a more gradual magnitude versus distance slope, i.e. a profile with a dull or flattened shape. Since this slope cannot be known in the absence of detection distance and apparent mass information, there is no mathematical basis for interpolation. This position error is exacerbated by the offset error. In upper and lower geographic latitudes where the offset error approaches zero, the spatial resolution error approaches unity as given by the sample rate and relative velocity. However, at middle latitudes, it may become a significant fraction of the total position error. In contrast, the spatial resolution of the embodiments of the present invention is not a function of the sample rate and velocity, and in fact, is completely independent thereof. Since the array in the embodiments of the present invention measures and collects information directly in the spatial domain, its spatial resolution is determined by the physical distance between the meters or sensors in the array. In order to collect meaningful vector gradient data, the sensors in the DGM array are spaced equally from each other. For example, a 6 meter long array with 13 sensors has a separation distance of 50 centimeters between each sensor (12 spaces), resulting in a spatial resolution of 25 centimeters. Since the array measures detection distance and apparent magnetic mass at the same time as it measures these 12 vector gradients, the magnitude/distance slope of the induced field surrounding the object can be quantified, thus providing the mathematical variables necessary for interpolation. In addition, the offset error for the DGM array is always zero regardless of the geographic location of the survey. These features represent a significant improvement in position error over conventional systems in the field of survey magnetometry.

The embodiments of the present invention offer an advantage over conventional systems as it relates to interference from nearby stationary objects that are not the subject of a search, test or inspection. If the magnitude of an induced field that surrounds a stationary object is greater than the resolution of a magnetometer in close proximity, the field may interfere with the operation, measurement accuracy or calibration of the instrument. Stationary in this context means the relative velocity between the interfering object and the instrument is zero, a ground or aerial vehicle to which a magnetometer is attached for example. Coincident magnetic fields vector sum, so depending on where measured, the induced field surrounding an object may be more than or less than the magnitude of the applied field. A traditional magnetometer in close proximity measures the vector sum of the interfering field and the applied field, the resultant value of which represents measurement error. If a vector measurement is sampled, the error includes both magnitude and direction. This type of error is evident in the deviation of a common compass in close proximity to a large metal object (such as a boat engine). Traditional magnetometers may employ countermeasures for this type of error, such as an adjustable or programmed offset, magnetic shielding, quadrantal spheres (Flanders balls or bars) or in situ calibration. These techniques have operational disadvantages that include added weight, increased circuit and/or software complexity, increased operational complexity, and in the case of in situ calibration, an additional magnetometer serving as a so-called base station used as a field reference. The embodiments of the present invention have the capability to annul this type of interference by means of a technique called normalization. Unlike conventional systems, a differential instrument such as the DGM array is intrinsically suited to manage static or time invariant interference. Since the array extracts information from an object's induced field by means of distributed differential measures, it is the change in the ground state of any sensor that provides information, not the absolute magnitude of its output. Consequently, any stable time invariant output of a sensor in the array can be registered as its ground state, regardless of its output value. Once the ground states of each of the sensors along the array have been registered, the output of each sensor is considered zero, regardless of its initial output magnitude. This is sensor output normalization. Subsequent to this procedure, any change in sensor output represents a change in the local field, which during search, surveillance, or inspection operation is necessarily an object of interest. This feature represents a significant improvement over conventional systems.

The embodiments of the present invention relate to the detection, measurement and characterization of the induced magnetic field that surrounds an object interacting with the earth's magnetic field or a man-applied magnetic field. In the case of interaction with the earth's magnetic field, the embodiments of the present invention also concern measuring certain properties of the object itself, such as apparent magnetic mass, which is that part of the object's mass interacting with the applied field, magnetic moment and orientation relative to some reference point or cardinal direction. In the case of interaction with a man-made man-applied field, the embodiments of the present invention also relate to detecting and measuring flaws, defects, or other discontinuities on the surface of, or within, some object being tested or inspected. In either case of interaction with the earth or a man-made magnetic field, the embodiments of the present invention further relate to locating an object in three-dimensional space relative to the differential gradiometric magnetometer (DGM) detection array, and/or relative to a grid, map or GPS reference. The embodiments include measuring the distance between the detection array and the object of interest or object under inspection (point to point detection distance). In some cases this translates to a depth measurement should the object be subterranean or submerged underwater. In other cases, it may translate into a target range.

The embodiments of the present invention comprise unique features including but not limited to the architecture of the magnetic field sensing array, the use of a plurality of field sensors or magnetometers in the array, the array's physical length and a dual modal technique for signal processing that enables the array to operate in both differential and gradiometric modes simultaneously. Further unique features reside in a means to capture both differential and gradiometric magnetic field data directly in the spatial domain, thereby extracting three-dimensional information required for location and mapping, as well as information about the object itself such as apparent mass and magnetic moment. Since information is captured directly in the spatial domain, these data can be displayed, stored/recorded and mapped in real time. Still further uniqueness resides in a means to nullify time variant source noise to near zero, thus rendering source signal-to-noise ratio for any given resolution and sample rate to near unity, nullify electromagnetic noise to near zero, and annul stationary object time invariant interference by means of sensor normalization.

In one embodiment, the array is comprised of a plurality of magnetic field sensors or magnetometers physically arranged in a linear geometric pattern. The field sensors are evenly spaced. In the case where a scalar or so called total field meter is used, all meters share a common coaxial alignment. If 1-axis or 2-axis vector sensors are employed, all sensors share a common orthogonal alignment. An example of this architecture is a series of sensors housed within a straight nonferrous tube such as fiberglass, carbon fiber, aluminum, etc. Another example is a series of magnetic sensors arranged on a semiconductor substrate constituting a micro or nanoscale array. Still another example of this architecture is a number of sensors attached to a data transmission cable.

In one embodiment, the lower limit for the number of sensors used in an array is three. However, the upper limit is only constrained by practical considerations such as weight, energy consumption and the physical size of the sensors or meters employed. For example, an array designed to surveil pedestrian traffic for concealed weapons may be 2 meters long and employ 21 sensors evenly spaced at 10 centimeter intervals. The spatial resolution of this array is an exceptional 5 centimeters. An array designed to examine geomagnetic strata along the depth of a well may employ thousands of sensors attached to a long data transmission cable. Cable arrays of this sort can be strung along a roadway or wrapped around an object like a machine part for the purpose of inspection, or around an area like a building for the purpose of surveillance.

Any type or kind of scalar or vector magnetic field sensor may be employed in the array depending on the task and prevailing operational requirements. In turn, the sensors or magnetometers may operate at any field magnitude resolution or vector angle resolution as may be appropriate for the application or task.

The size of the induced magnetic field surrounding an object interacting with an applied field may be defined as that equipotential spheroid equal in magnitude to the resolution of the instrument. A necessary requisite for the proper function of the DGM array is that its length be sufficient to encompass the object's field spheroid, as defined above, extending through it and beyond either side by at least one sensor-to-sensor space. For example, for an array operating at a resolution of 0.5 ηT designed to detect and measure the induced field surrounding land mines, 6 meters in length is sufficient for any mine size or mass.

Prior to operation, the array is normalized by positioning it relative to any stationary objects and away from any search, surveillance or inspection objects of interest. By means of a simple software algorithm, the output magnitudes of all sensors or meters in the array are stored in computer memory by means of a sample and hold technique. All such samples are taken at the same point in time correlated by a master high-speed clock. The difference between these sensor output magnitudes and the output magnitude of one sensor presenting the lowest value is calculated and stored in memory registers, each register associated with, and dedicated to, a single sensor. These difference values then become operands which are subtracted from the actual output magnitude of each sensor including the reference sensor, thus forming a third set of data correlated with, and dedicated to, each sensor. This third set of correlated magnitudes become the normalized output of the sensors in the array, and remain zero value until some object of interest comes near the array, or the array is brought near an object of interest. After the normalization procedure, which is akin to initializing the array, the first data set is allowed to vary according to sensor output for each sample measure taken. The second set of registered data, the operands, is stored in computer memory and remains unchanged until the next normalization procedure, which can be initiated at any time required by a change in operating conditions or environment. The third set, the difference between the output magnitudes and the registered operands, represents the raw data for the functional algorithms. When the magnetic field surrounding an object of search, surveillance or inspection is presented to the sensors in the array, the value of the registered operands in storage are subtracted from the actual sensor output each time the field is sampled, hence, the output data set only reflects changes in the magnitude of the sensors. These three data sets enable the system to respond to changes in the magnetic field presented to the array, which in either case of a search/survey, surveillance or inspection, is field data characterizing an object of interest. This information is also used by the system to calculate or otherwise extract information about the object itself. This procedure has utility for two reasons. First, it nullifies magnetic field interference from stationary objects, a useful feature for any magnetometry application. Second, it effectively annuls any sensor to sensor differences inherent in device response, circuit to circuit differences inherent in the interface and signal processing circuitry, and other differences inherent in connecting wires, cables, connectors etc.

In one embodiment, during normal operation, field data are sampled at some appropriate rate by means of a conventional sample and hold technique. Sampled data is taken from all sensors at the same point in time, correlated by a master high-speed clock, and temporarily stored in computer memory as an output data set corresponding to each sensor in the array as described above. During the period between successive samples, two independent digital signal processing algorithms operate on the normalized data set simultaneously. One algorithm computes the differential scalar flux density of the object's induced field by first analyzing all normalized data points and selecting one with the lowest magnitude (value). This is accomplished by means of a conventional infimum software engine. The normalized output of this sensor is tagged as a reference datum, and subtracted from the normalized output values of the remaining sensors or meters. These scalar magnitude data are the differential field measure for that sample period. These data points are then correlated to the location or position of the sensors in the array, and used to generate a spatially differentiated cross-sectional contour of the magnetic field under inspection. The correlated data sets can then be stored in computer memory or otherwise recorded for later use, immediately displayed in real time to the operator during a search or surveillance operation, or compiled with previous contour data sets to generate a location map as a survey proceeds, or a flaw/defect map as an inspection is conducted. At this point in the process of extracting and computing information, map data contain only two-dimensional information, i.e. information in the x-y plane only.

In one embodiment, during the same period as the differential algorithm is operating, a second independently running software algorithm operates on the same normalized sensor output data for the purpose of extracting simultaneous gradiometric field measurements. This software algorithm subtracts the normalized output data of each sensor in the array from its immediate neighbor, and stores these resultant values in a memory register correlated with, and dedicated to, positions along the array midway between each sensor. The algorithm then divides these resultant values by the fixed distance between each sensor, thus transforming scalar magnitudes into vector quantities representing field gradient information. These data characterize the gradiometric cross-sectional contour of the field under inspection, capturing it directly in the spatial domain. As a final step, these data are used as operands to calculate detection distance as range, depth if the object is subterranean or submerged, the apparent magnetic mass of the object, and the object's magnetic moment. Distance, mass and moment information is then added to the information calculated and compiled by the differential algorithm for immediate display to the operator, data storage or recording, and most importantly, to transform two-dimensional map information into three-dimensional map information that includes detection distance as range, or object depth.

The DGM system is useful for detecting, locating, mapping and object characterization of surface, subterranean, and submerged land or marine mines, improvised explosive devices (IEDs), explosively formed projectiles (EFPs), unexploded ordnance (UXO), as well as objects of archeology or buried treasure interest. It would also have utility for surveillance of submerged vessels, ground vehicles, and pedestrian traffic for the purpose of detection, location, counting, and object characterization of the object itself or concealed objects like weapons and suicide bomb vests. Further utility would be the inspection of parts or materials for flaws, defects, and other discontinuities, as well as for object characterization as to size (mass), process staging, process timing, counting, etc. Still further utility would be for measuring and/or monitoring geomagnetic features such as geologic strata down a well, or monitoring changes in the geomagnetic character along an earthquake fault line.

Other variations, embodiments and features of the present invention will become evident from the following detailed description, drawings and claims.

### BRIEF DESCRIPTION OF DRAWINGS

FIG. 1 depicts one example of a complete DGM system showing an option of two sensing arrays, one connected by electric or fiber optic cable, and the other one connected via a radio telemetric link;

FIG. 2 depicts the geometric architecture of one example of a DGM array 6 meters in length employing 13 magnetometers or sensors;

FIGS. 3a, 3b and 3c depict the axial alignment of the meters or sensors in a DGM array showing in FIG. 3a the coaxial alignment for scalar meters, in FIG. 3b the orthogonal alignment for 1-axis sensors, and in FIG. 3c the orthogonal alignment for 2-axis sensors;

FIG. 4 shows the steps, data flow and formulary for the Sensor Data Normalization Algorithm wherein the algorithm normalizes sensor output data as to sensor-to-sensor variation as well as from time invariant or static nearby stationary objects;

FIG. 5 depicts an example of Sensor Output Normalization Data as collected by the array, stored in computer memory, and operated on by the Sensor Data Normalization Algorithm with three data sets (Mₒ, Mₛ, and Mₙ) shown;

FIG. 6 shows the steps, data flow and formulary for the Differential Measurement Algorithm wherein the algorithm operates on normalized sensor outputs as a means to generate scalar differential magnetic field measures;

FIG. 7 depicts an example of Differential Measurement Data as collected by the array, stored in computer memory, and operated on by the Differential Measurement Algorithm with seven data sets (Mₒ, Mₛ, Mₙ, Mᵣ, Mₐ, M′ᵣ, and M_{d}) shown;

FIG. 8 shows the steps, data flow, and formulary for the Gradiometric Measurement Algorithm wherein the algorithm operates on normalized sensor outputs as a means to generate vector gradient magnetic field measures;

FIG. 9 depicts an example of Gradiometric Measurement Data as collected by the array, stored in computer memory, and operated on by the Gradiometric Measurement Algorithm with eight data sets (Mₒ, Mₛ, Mₙ, Mᵣ, Mₐ, M′ᵣ, M_{d}, and M_{g}) shown;

FIG. 10 depicts an example of a Real Time Display of differential magnetic data after sensor output normalization and before an object of interest is presented to the array (no target); and

FIG. 11 depicts and example of a Real Time Display of differential magnetic data when an object of interest is presented to the array (target is being detected).

### DETAILED DESCRIPTION

It will be appreciated by those of ordinary skill in the art that the invention can be embodied in other specific forms without departing from the spirit or essential character thereof. The presently disclosed embodiments are therefore considered in all respects to be illustrative and not restrictive.

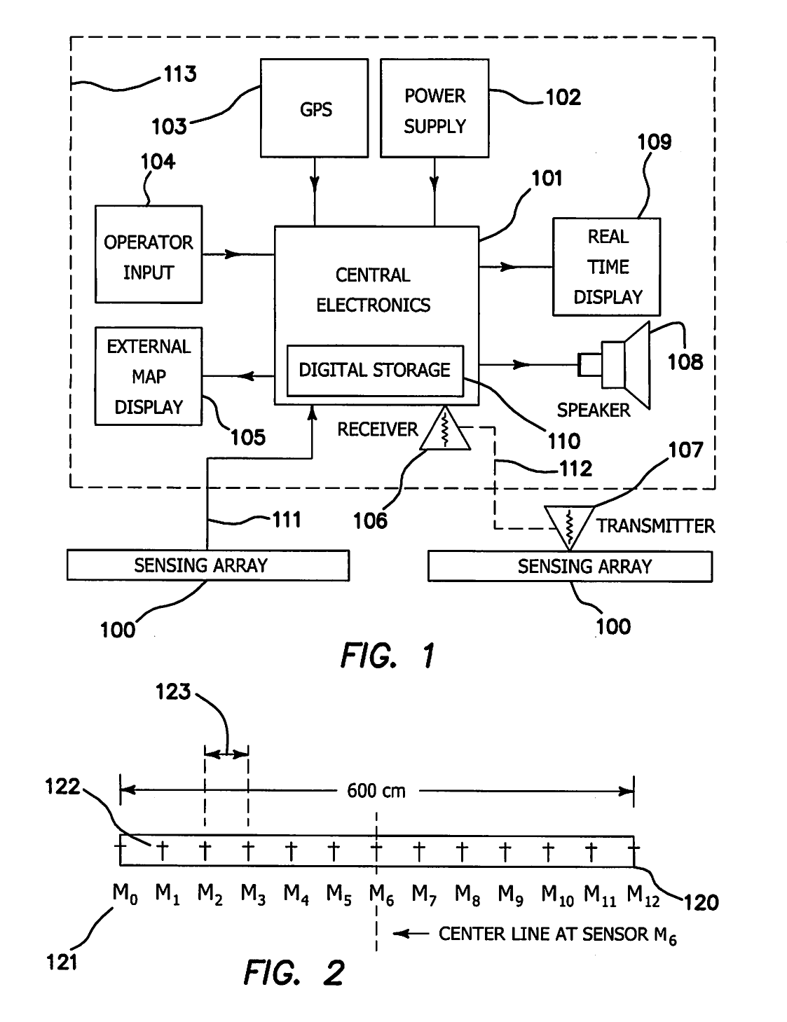

FIG. 1 depicts an exemplary DGM system. Depending on how the DGM is tasked, other complete system configurations are possible. This example is provided as a means to explain how the DGM array and the signal processing algorithms integrate into a functional system for magnetometry survey, surveillance and/or inspection function.

The array is a linear arrangement of a plurality of magnetic sensors or magnetometers. In FIG. 1, two arrays 100 are shown to demonstrate that it can be interfaced with a central electronics unit 101 by means of electric conducting or fiber optic cabling 111, or by radio transmission telemetry 112 via a transmitter 107 and receiver 106. A speaker, headphone or earpiece 108 can be provided as a means to alert the operator to the detection of an object of interest in the case of a magnetic survey, a land mine for example, a vehicle or pedestrian carrying a concealed weapon in the case of magnetic field surveillance, or a flaw, defect, count, under or over mass or process timing or staging error in the case of inspection duty. The real time display 109 can be any operator display such as LCD, CRT, plasma screen, etc. The real time display 109 presents a cross-sectional profile of the magnetic field surrounding an object in real time (note an example of this type of display in FIG. 11). This information is useful for detection, location and object characterization as to orientation relative to the array, compass direction or some other reference point. Information as to object location, mass and detection distance (depth if subterranean or submerged) can also be displayed in real time providing the altitude of the array is known. A power supply 102 can be a battery, photo voltaic cell or line electricity depending on the task and/or availability of electric energy. A GPS unit 103 is shown to demonstrate that the location of the DGM system or just the array can be integrated for the purpose of mapping function and/or location of detected objects. An operator input 104 comprises input switches, dial settings and indicator lamps as may be required by system input functions. An external map display 105 is differentiated from the real time display 109 in that it displays three-dimensional information as an overlay on a map or grid reference. The DGM system has the capacity to map and display detected objects to the operator in real time. Digital storage 110 can be provided as a means to collect magnetic field information during a search, surveillance or inspection operation and used at some latter time for analysis. The dotted line at 113 indicates those components which may comprise any number of other components as required by the magnetometry objective.

FIG. 2 depicts an exemplary DGM array 120 six meters long employing 13 sensors or magnetometers 122. The sensors 122 are labeled M₀ through M₁₂ 121 with the centerline of the array marked as M₆. The dimension 123 indicates that the distance between each sensor is equal and common to all sensors regardless of the number of sensors employed. This equal distance is beneficial for proper gradiometric measurement. In such an embodiment, the minimum number of sensors is three. However, the upper limit is only constrained by engineering and/or environmental considerations (such as weight, energy consumption, task or duty, length of the array, etc.). Any type of magnetic sensor 122 or meter may be used with the array 120 including vector, scalar or gradiometric types.

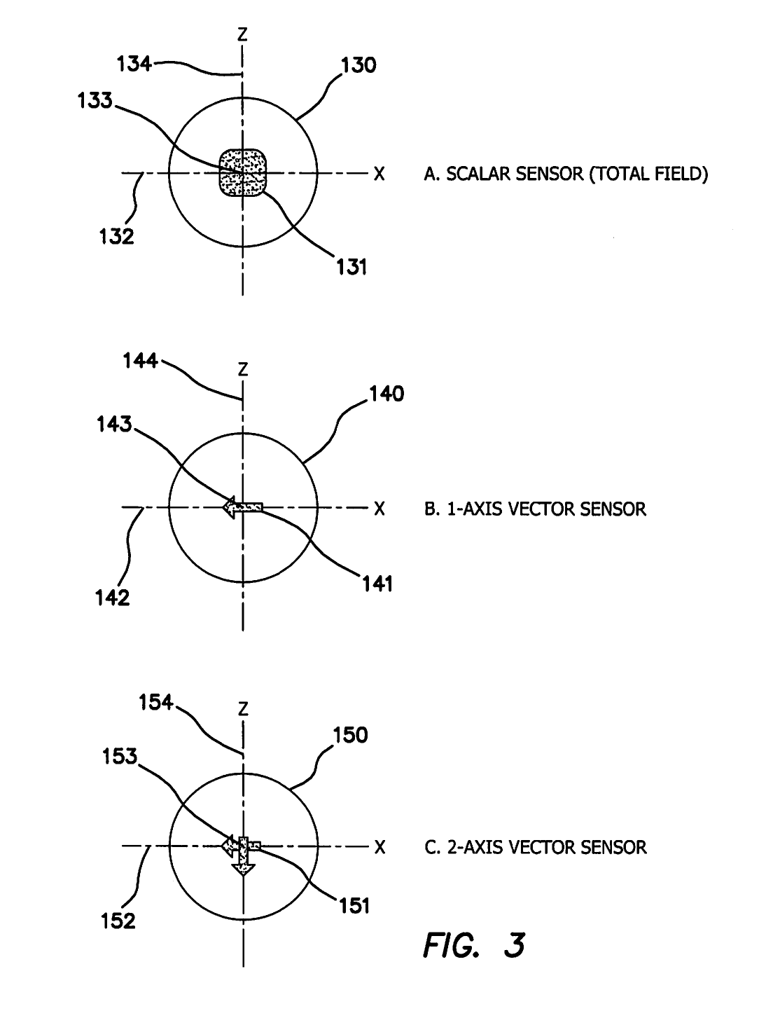

FIGS. 3a, 3b, and 3c depict sensor alignment along the DGM sensing array 120. In each of the three figures, the x-axis 132, 142 and 152 is associated with a horizontal orientation parallel to an earth plane tangent, the y-axis 133, 143 and 153 is the orthogonal complement of the x-axis 132, 142 and 152 into or out-of the page, also associated with a horizontal orientation. The z-axis 134, 144 and 154 is associated with a vertical direction perpendicular to an earth plane tangent. In the case of scalar (total field) type magnetometers 131, as shown in FIG. 3a, the central response point of the magnetometers 122 is aligned coaxially along a common line or axis 133 associated with the array 120. The position of this common axis may be central to the interior of an array, such as along the center axis of a tube 130, 140 or 150 as shown, along the side of an array, such as along one side of a data transmission cable (not shown), or along a common line on the surface of a substrate (not shown). FIG. 3b details the alignment of single-axis vector type sensors 141. The primary response axis of the sensors 141 aligns with one of the three position axes, x, y, or z, and shares a common orthogonal orientation. The same alignment is used for 2-axis vector sensors 151 as shown in FIG. 3c. The primary response axis of all sensors aligns to one of six positions x-y, y-x, x-z, y-z, z-x, or z-y, and share a common orthogonal orientation.

A plurality of magnetic field sensors, together with a plurality of interface and support electronic circuitry, necessarily exhibit sensor-to-sensor or electronic unit-to-unit output variations even in the presence of a homogeneous time invariant magnetic field. In addition, these unit-to-unit variations change or drift over time as a function of changes in operating and/or device temperature, as well as with other factors that cause instrument drift or instability. Consequently, over short periods of time, such variations may be considered time invariant, yet over longer periods, they may change, albeit slowly. Hence, these types of instrument output variations may be considered time invariant or quasi time invariant. During magnetometry survey, surveillance or inspection operation, nearby stationary objects interacting with local magnetic fields may present induced fields to a magnetometer that represent interference. For example, a magnetometer attached to a ground vehicle searching for land mines is immersed in the induced magnetic field surrounding the vehicle. This field may represent resolution, sensitivity or calibration interference for traditional magnetometers. It is particularly problematic for traditional gradiometers since the induced magnetic field surrounding a nearby stationary object changes the local field gradient. These induced magnetic fields will change direction, orientation and magnitude as the earth's ambient field changes. Hence, although somewhat time invariant over short periods, theses types of interference may also be considered quasi time invariant.

Since the DGM array 120 is designed to affect differential field measurements, it is uniquely capable of mitigating such variations by means of computer software algorithm. The array 120 extracts information from an object's induced magnetic field by means of distributed differential measures. It is the change in the output of any sensor 122 that provides information, not the absolute magnitude of its output. Consequently, any stable time invariant output of a sensor in the array 120 can be registered as its ground state, regardless of its output value. Once the ground states of each of the sensors 122 along the array 120 have been registered, the output of each sensor 122 is considered zero, regardless of its initial output magnitude. This is sensor output normalization. Subsequent to this procedure, any change in sensor output represents a change in the local field, which during search, surveillance or inspection operation is necessarily an object of interest.

Sensor output normalization annuls time invariant variations and interference. For quasi time invariant variations and/or interference, i.e. those that change slowly over long periods, sensor output normalization may be periodically reinitiated. For example, the earth's ambient magnetic field vector changes in magnitude, direction and inclination over diurnal periods. Depending on geographic location, the magnitude of diurnal changes can be on the order of +/−100 ηT, resulting in rate changes on the order of 10 s of ηT per hour or more. This may be problematic for search, survey or surveillance magnetometry with long operational periods. After initial sensor output normalization, quasi time invariant variations and/or interference can be easily monitored, and when excessive, sensor output normalization can be repeated as a means to compensate. Since the embodiments of the present invention do not require calibration or calibrated measurements, periodic sensor output normalization can be initiated by operator input when needed, or affected automatically by means of computer software and electronic circuitry without the need for any reference outside of the DGM system itself.

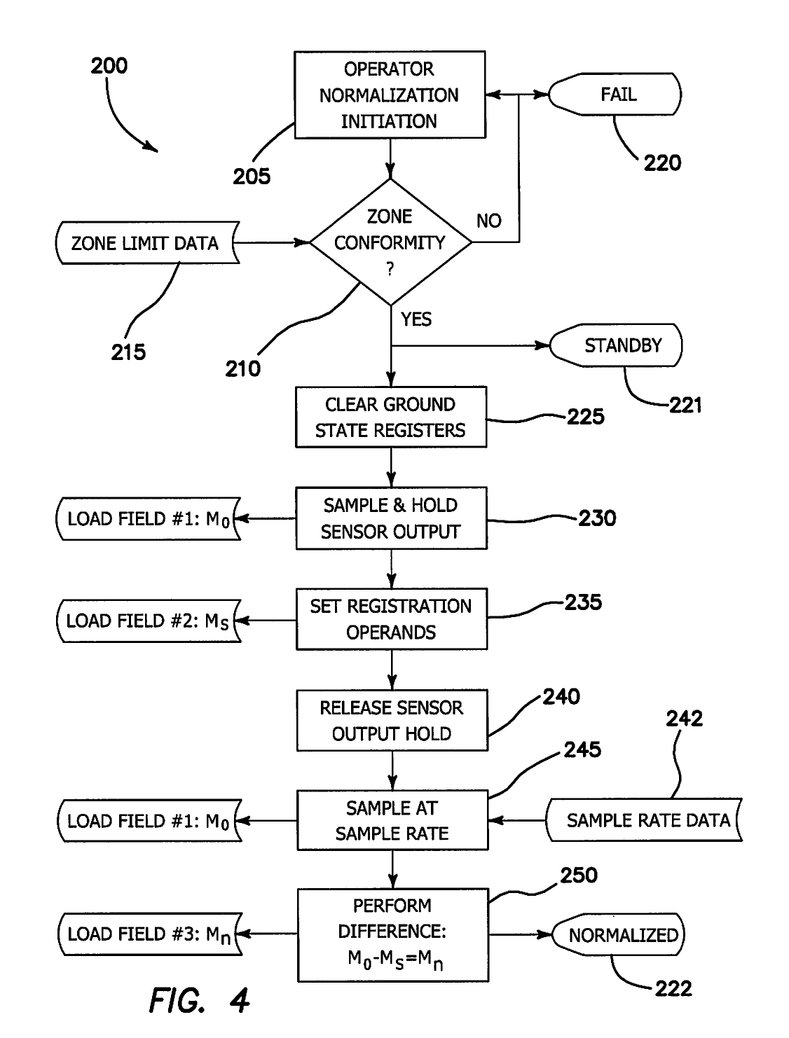

FIG. 4 details the operation of the algorithm 200 for sensor output normalization of the embodiments of the present invention by showing the principal steps, logic, data flow and formulary. It begins with operator input, shown as Operator Normalization Initiation 205, or automatic initiation (not shown). Zone conformity 210 is a range of sensor output variation or interference stored in computer memory, the value of which depends on the operational and environmental conditions precedent. If the magnitude of the variation or interference is outside the preset zone limits 215, normalization fails 220. This is indicated by the yes/no logic step labeled “Zone Conformity?” Indicator lamps for Fail 220, Standby 221, and Normalized 222 are shown for clarity. If the variation or interference is within the zone limit, the algorithm proceeds by first clearing any data in the Ground State Registers 225 (computer memory). Next, the output values of the sensors 122 or meters in the array 120 are sampled once, and loaded or stored in computer memory. This is indicated by the step labeled Sample & Hold Sensor Outputs 230, and Load Data Field #1: Mₒ, Mₒ is a term representing sensor/meter output values, subscript “o” denoting “output.” The values of Mₒ are then stored in a separate computer data field memory as Mₛ for each sensor or meter in the array 120. The term Mₛ represents ground state sensor values, subscript “s” denoting “ground state.” This step is labeled Set Registration Operands 235 and Load Data Field #2: Mₛ. The sensor sampling hold is then released at step Release Sensor Output Hold 240. The algorithm then begins to sample sensor output values at a preset sample rate as may be required by the operational, engineering or environmental conditions precedent. These values 242 are held in computer memory for each sample period as Mₒ. This step is indicated by the label Sample at Sample Rate 245 and Load Field #1: Mₒ. The final algorithmic level is denoted by the label Perform Difference: Mₒ−Mₛ=Mₙ, 250 and Load Field #3: Mₙ, where Mₙ represents normalized sensor output values or data, subscript “n” denoting “normalized.” This is expressed mathematically by:

Mₙ=Mₒ−Mₛ. (1)

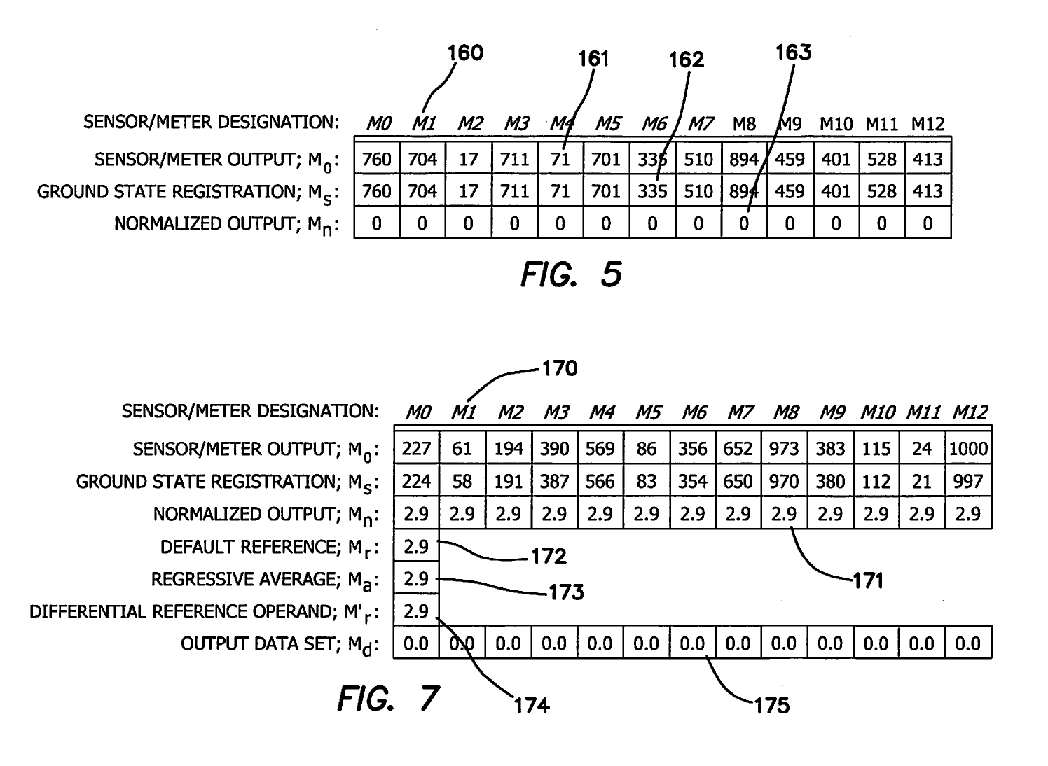

FIG. 5 is an example of the data collected and stored during the sensor normalization procedure. The top line in the table 160 denotes the sensor/meter designations. Thirteen sensors 122 are shown in this example designated M0 through M12, but any number from three (3) sensors to some indeterminate upper limit may be subject this technique depending on the number of sensors 122 in the array 120. The second line in the table labeled Sensor/Meter Output: Mₒ is data field #1 161 representing the output values of each sensor 122 in the array 120. The third line in the table labeled Ground State Registration: Mₛ is data field #2 162 representing the operands Mₛ used by the algorithm for calculating the normalized data outputs. The fourth line in the table labeled Normalized Output: Mₙ is data field #3 163 representing the normalized output data as Mₙ=Mₒ−Mₛ. The values presented are arbitrary units.

The employment of a plurality of magnetic sensors arranged in a particular linear geometric architecture of the embodiments of the present invention enables the DGM system to extract or otherwise measure differential field information. Unique in this regard is that magnetic field information is sampled by taking the difference between only one sensor 122 in the array 120, representing a reference, and all other sensors 122 in the array 120. Since each of the sensors 122 in the array 120 experience and measure short period time variant source and artificial magnetic noise at the same time and at the same magnitude, subtracting the output value of the reference sensor, designated as M′ᵣ, from the normalized output values Mₙ, effectively nullifies such noise to a near zero value. These differential output values M_{d}, subscript “d” denoting “differential,” are rendered to a near zero level due to the fact that the earth's magnetic field presents a natural gradient on the order of ˜0.2 pT/meter (1 pT=one picotesla=10⁻¹² tesla). Since the DGM array may be a number of meters long, this accounts for the small amount of gradient source noise expressed in the differential measure of M_{d}. The differential measure is resolved by the last step in the Differential Measurement Algorithm by:

M_{d}=Mₙ−M′ᵣ. (2)

The reference sensor is selected by the Differential Measurement Algorithm by first compiling the normalized output values Mₙ from a set “S” of sensors established by the operator or designer of the system. The set S is stored in computer memory for use by the Differential Measurement Algorithm. After the normalized output values Mₙ are compiled as elements of S, the algorithm calculates the infimum element there from. In this case, the infimum represents the normalized output value Mₙ from set S that is closest to zero value. For the following formulary, let the set S contain the normalized output values of the first and last sensors in the array 120, designated as M_{f} and Mₗ where the subscripts “f” and “l” denote “first” and “last,” respectively. The set S may contain any finite number of elements from one to the total number of sensors in the array 120. For this example, this level of the algorithm is given by:

S′={[M_{f}],[Mₗ]}, (3)

where prime S′ represents the particular set {M_{f},Mₗ}, and

MᵣεS′:inf(S′)=inf{[M_{f}],[Mₗ]}, (4)

which has the algebraic solution:

$${m}_{r} ∈ {S}^{′} \text{:} inf ( {S}^{′} ) = \frac{\vert {M}_{f} \vert + \vert {M}_{i} \vert}{2} - \frac{\vert \vert {M}_{f} \vert - \vert {M}_{i} \vert \vert}{2} , \qquad ( 5 )$$

generating that element of S′ nearest to the value of zero. Absolute values of M_{f} and Mₗ are used because some values of Mₙ may be negative.

Mᵣ is the default value of the reference sensor. However, in some circumstances, the array 120 may transect an object's induced field where the ends of the array 120 are still entirely within the induced field, i.e. not extending into the unperturbed earth ambient magnetic field. This is the case where the array 120 is shorter than, or too close to, the induced field presented by an object. In this circumstance, Mᵣ as calculated by equation (5) contains an error equal to the field magnitude of the earth's magnetic field presented to Mᵣ. Normally, the value of Mᵣ would be that element of S nearest to value zero, and therefore nearest to the normalized ground state value of the earth's field as measured. To account for this, the Differential Measurement Algorithm averages the previous n values of Mᵣ and compiles a data set P comprised as {Mₐ, Mᵣ}, where Mₐ is the regressive average of n samples, subscript “a” denoting “regressive average.” The number n samples is established by the operator or designer of the DGM system, and stored in computer memory for use by the Differential Measurement Algorithm. The infimum of set P is then determined to generate the greatest lower bound of P representing the value of M′ᵣ in equation (2).

Mᵣ is held in computer memory as a means to compare its value with the average of the previous n values of Mᵣ as Mₐ, where:

$${M}_{a} = \frac{\{ {M}_{r - 1} + {M}_{r - 2} + … {M}_{r - n} \}}{n} , \qquad ( 6 )$$

where n is the number of previous values of Mᵣ constituting a range for Mₐ having the solution:

$${M}_{a} = \frac{{\sum }_{i = 1}^{n} {M}_{r ( i - 1 )}}{n} . \qquad ( 7 )$$

The value from equation (7) as Mₐ and the current value of Mᵣ are then compiled into set P as:

P={Mₐ,Mᵣ}, (8)

whereupon the algorithm computes the infimum of P given by:

$${M}_{r}^{′} ∈ P \text{:} inf ( P ) = inf \{ {M}_{a} , {M}_{r} \} = \frac{{M}_{a} + {M}_{r}}{2} - \frac{\vert {M}_{a} - {M}_{r} \vert}{2} , \qquad ( 9 )$$

thus selecting that element of P representing the greatest lower bound as M′ᵣ used in equation (2) to calculate the differential measures M_{d} given by:

M_{d}=Mₙ−M′ᵣ. (2)

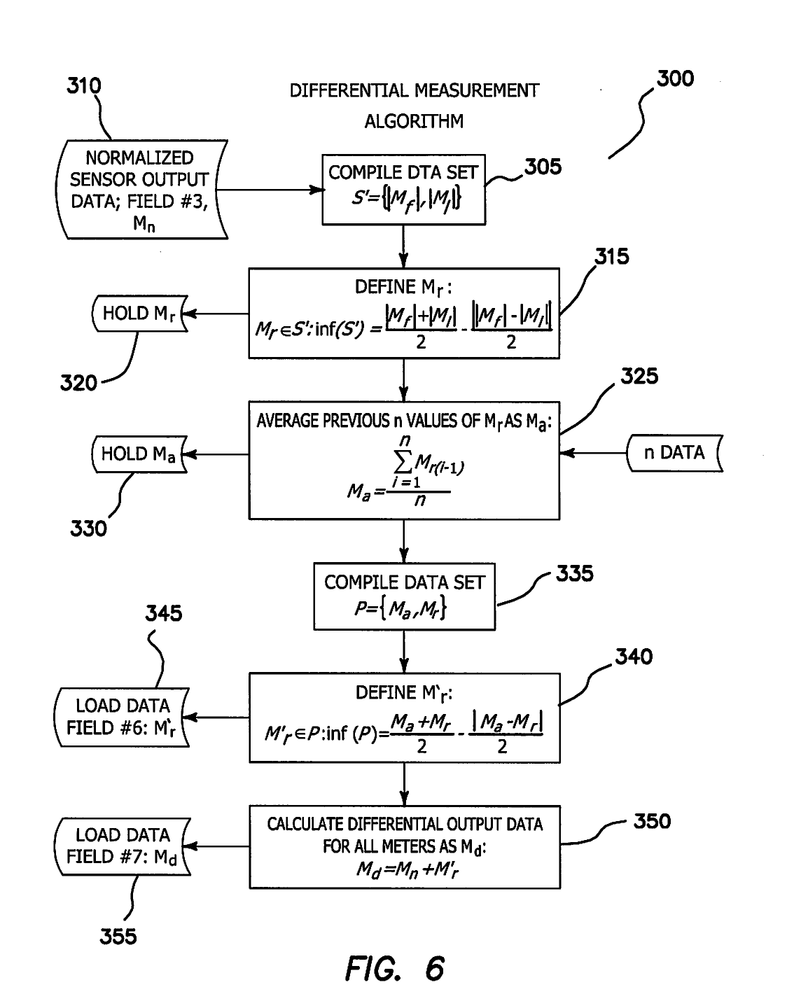

FIG. 6 details the algorithm 300 for differential measurement employed by the embodiments of the present invention by showing the principal steps, logic, data flow and formulary. It begins by compiling the data set S′ using stored values of normalized sensor outputs Mₙ in data field #3 as defined by the operator or designer of the DGM system. This step is labeled Compile Data Set S′={M_{f}, [Mₗ]} 305 and Normalized Sensor Output Data; Field #3 Mₙ 310. The algorithm 300 then calculates the greatest lower bound element of S′ according the infimum equation (5), and holds this value as Mᵣ in computer memory. This step is labeled Define Mᵣ [equation (5)] 315 and Hold Mᵣ 320. The average of the previous n values of Mᵣ is then calculated. The value of n is established by the operator or designer of the system and stored in computer memory for use by the algorithm. This level of the algorithm 300 is labeled Average Previous n Values of Mᵣ as Mₐ [equation (7)] 325 and Hold Mₐ 330. The set P={Mₐ,Mᵣ} is compiled 335 from this regressive average and the current value of Mᵣ. The greatest lower bound of P is then extracted by means of an infimum function. This level of the algorithm is labeled Define M′ᵣ [equation 9] 340 and Load Data Field #6: M′ᵣ 340, wherein the prime indicates that it is the second time the element Mᵣ has been compiled and extracted. The value of M′ᵣ is now available for the computer to resolve the differential measurement values for each sensor or meter in the array. This is done by means of equation (2). This last step in the Differential Measurement Algorithm 300 is labeled Calculate Differential Output Data for all Meters as M_{d} [equation (2)] 350 and Load Data Field #7: M_{d} 355.

FIG. 7 is an example of the data collected, compiled, calculated and stored during the differential measurement procedure. A computer program emulates the Differential Measurement Algorithm as described above. This software program generated the numbers displayed in FIG. 7. The numbers shown in the table are arbitrary units. The top line in the table 170 represents sensor designations. Thirteen sensors are shown in this example labeled M0 through M12, but the DGM array may employ any number of sensors equal to or greater than 3. Data field #3 171 is labeled Normalized Output; Mₙ: which contain the stored values of normalized sensor outputs for each sensor in the array. Data field #4 172 contains the stored value of the default reference sensor Mᵣ. Data field #5 173 contains the stored value of the regressive average of n values of Mᵣ as Mₐ. Data field #6 174 contains the stored value of the differential operand M′ᵣ. Data field #7 175 contain the stored values of the differential measurements for each sensor in the array as M_{d}. It is these data that are available for real time display to the operator or real time compilation for mapping functions. Random source noise 171 was introduced to the computer simulation as a means to demonstrate how the Differential Measurement Algorithm annuls such noise.

The novel linear geometric architectures of the sensing array comprising the embodiments of the present invention enables the DGM system to extract vector gradient information from the induced magnetic field surrounding an object interacting with an applied magnetic field. This is accomplished by means of a Gradiometric Measurement Algorithm which operates on the normalized sensor output data Mₙ, at the same time as the Differential Measurement Algorithm is operating on the same data. This unique design feature and novel signal processing technique enables the DGM system to map detected objects in three-dimensions, and do so in real time. This is possible because the DGM array captures differential and gradiometric field information directly in the spatial domain at one point in time, as opposed to capturing information in the time domain over some period.

The distance between any two sensors 122 or meters in the array 120 is fixed and common throughout its length. For example, a 6 meter long array employing 13 sensors has a sensor-to-sensor separation distance of 50 cm. Using the normalized sensor output values Mₙ, the Gradiometric Measurement Algorithm subtracts the output value of one sensor from its immediate neighbor or from one sensor to some distant sensor in the array as specified by the operator or designer of the DGM system. This is done as a means to calculate the scalar difference between the designated sensor pairs. Non-neighboring sensor pairs can be used for this calculation if a field gradient measurement is required over a larger distance for some magnetometry objective. The Gradiometric Measurement Algorithm then divides this scalar difference by the distance between the designated sensor pairs as a means to calculate a vector gradient measure.

The algorithm first compiles or otherwise retrieves from computer memory an input data set G comprised of elements of Mₙ according to the sensor-to-sensor pairs established by the operator or designer of the system. G is given by:

G={Mₙ:Mₙ₊₁,Mₙ₊₁:Mₙ₊₂ . . . , Mₙ₍ₙ₋₁₎:Mₙ₊ₙ}. (10)

In this example, neighboring sensor pairs are employed; however, sets of any two pairs of sensor in the array may be used depending on the gradient distance required. The difference between each sensor pair is then calculated for all elements of G:

Mₙ:Mₙ₊₁εG:M_{gn}=Mₙ−Mₙ₊₁, (11)

where M_{gn} represents the differential scalar magnitude between each sensor pair in G. The final level of the algorithm is to divide M_{gn} by the distance between the sensor pair:

M_{g}=M_{gn}/dₘ, (12)

where M_{g} represents the vector gradient between each sensor pair in the array, and dₘ is the distance between the sensor pairs, subscript m denoting “meter.”

This procedure generates a series of vector gradient measurements evenly distributed along the length of the array. These measures are also correlated to positions along the array at the center point midway between each designated sensor pair. This gradiometric information is used by the DGM system to calculate the distance between the center point of each sensor pair and the object under inspection. Depending on the number of sensor pairs in the array, a number of these distance calculations are generated. From these (only two are required), the object's location along the z-axis relative to the array can be resolved by simple trigonometric computation. This information is added to the two-dimensional x-y axes information generated from differential measurement data as a means to complete a three-dimensional data set useful for mapping. Both sets of information, scalar differential and vector gradiometric, are captured directly in the spatial domain at the same point in time. This means that multiple field measurements are sampled at regular distance intervals instead of a regular time intervals. Since the differential and gradiometric computer algorithms operate on normalized sensor output data simultaneously, the object's location in three-space is available in real time.

Since the magnitude of an induced magnetic field diminishes over distance at predictable rates common to all dipoles, by 2/r³ radially and 1/r³ tangentially, if the magnitude and gradient of the field is known at some distance from the object, the object's apparent magnetic mass and magnetic moment are easily calculated. This information may be useful for a variety of magnetometry objectives. For example, prior to digging for a land mine, it would be very useful to have knowledge about its mass, physical size, shape, orientation, location and depth—all of which can be provided by the embodiments of the present invention in real time.

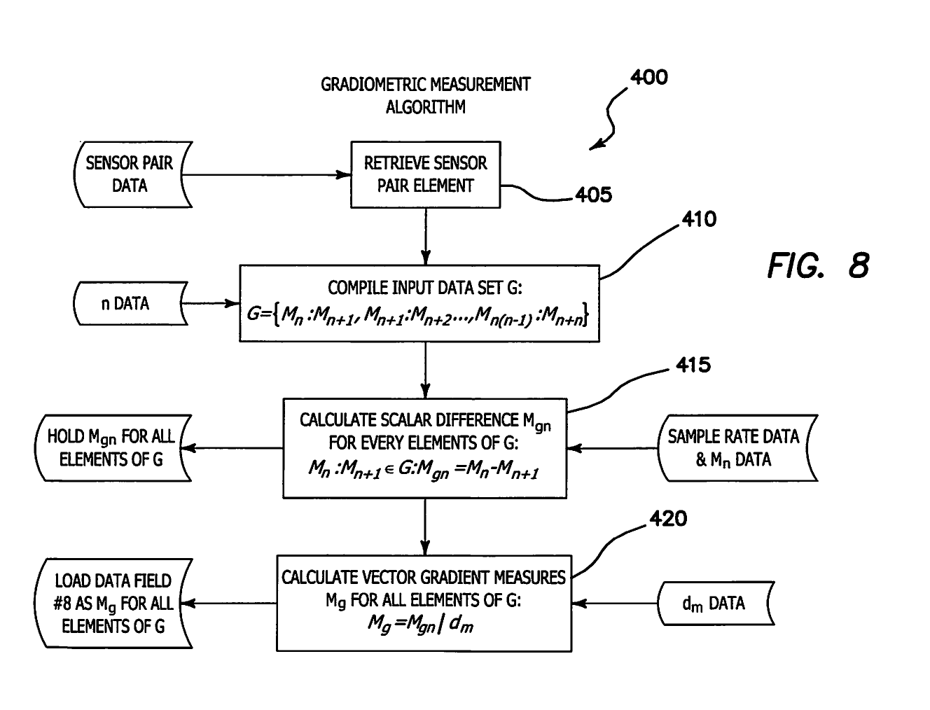

FIG. 8 details the steps, logic, data flow and formulary for the Gradiometric Measurement Algorithm 400 of the embodiments of the present invention. It begins by retrieving the designated sensor pairs from computer memory previously established by the operator or designer of the system. This first level of the algorithm 400 is labeled Retrieve Sensor Pair Element 405. The next step is to compile the input data set G shown at Compile Input Data Set G: [equation (10)] 410. Using sample rate and normalized sensor output data Mₙ, the differential scalar magnitude of each element of G is calculated at the level labeled Calculate Scalar Difference M_{gn} [equation (11)] 415. M_{gn} data is held in computer memory for the final step in the algorithm, calculating the vector gradient M_{g} indicated as Calculate Vector Gradient Measures . . . [equation (12)] 420. Solutions to equation (12) are loaded into data field #8 as M_{g} for all elements of G. These data are the gradiometric field measures.

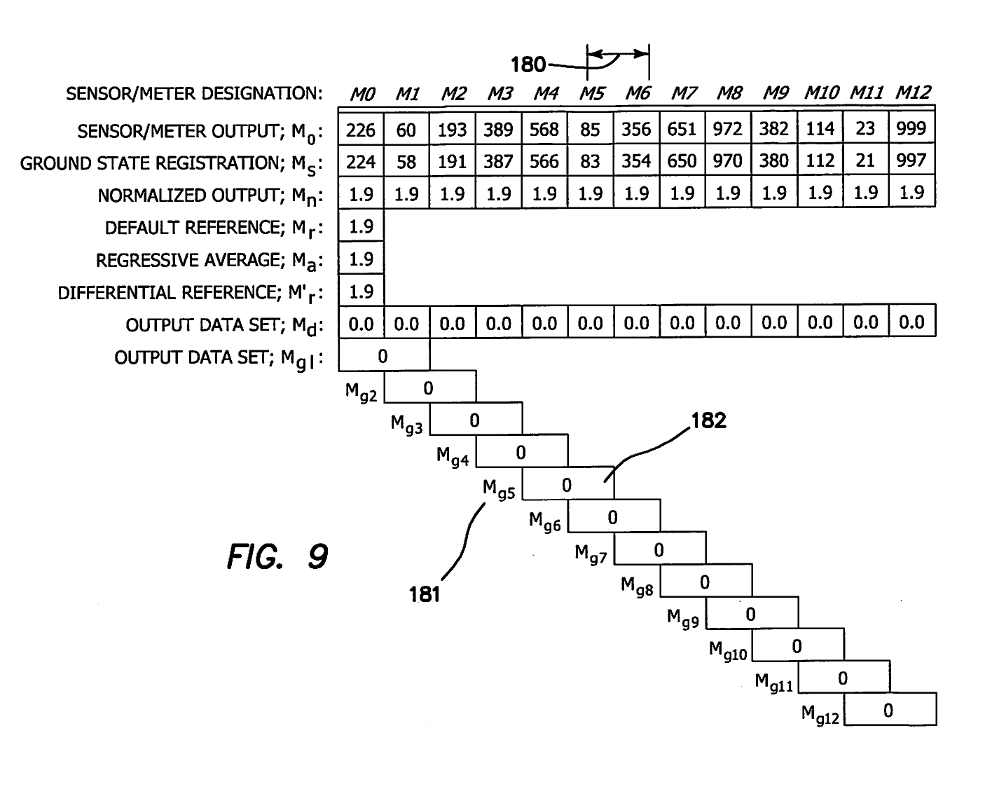

FIG. 9 is an example of the data collected, compiled, calculated and stored during the gradiometric measurement procedure. The first 8 lines of the table are as before (see FIG. 7). The icon at 180 indicates that neighboring sensor pairs were used for the gradient measurements in this example. Since gradient information is a magnitude over distance measure, 12 such measures are possible with the 13 sensor array in this example. More or less sensors may be employed in any array depending on the spatial resolution required by the magnetometry objective. The vector gradient measurements are designated M_{g1} through M_{g12} 181, representing positions along the array located at the center point midway between each designated sensor pair. The output value for each measurement sample is shown adjacent to the designation 182. For this example, the sensor pairs are neighboring, but any two sensors in the array may be designated as a pair. If the space between two independent sensors is used for the measurement, M0:M1, M0:M12, or M3:M7 for example, the first spatial derivative of the field can be extracted for each pair. If two spaces are considered, such as M0:M1 and M0:M2, the second spatial derivative can be extracted. As an example, the meter pair elements in set G could be arranged thus:

G={M0:M1,M0:M2,M0:M3 . . . , M0:M12}.

Note that the meter M0 is used as a common doublet for all pairs. Vector gradient information of this type provides a very high order resolution for any calculated parameter.

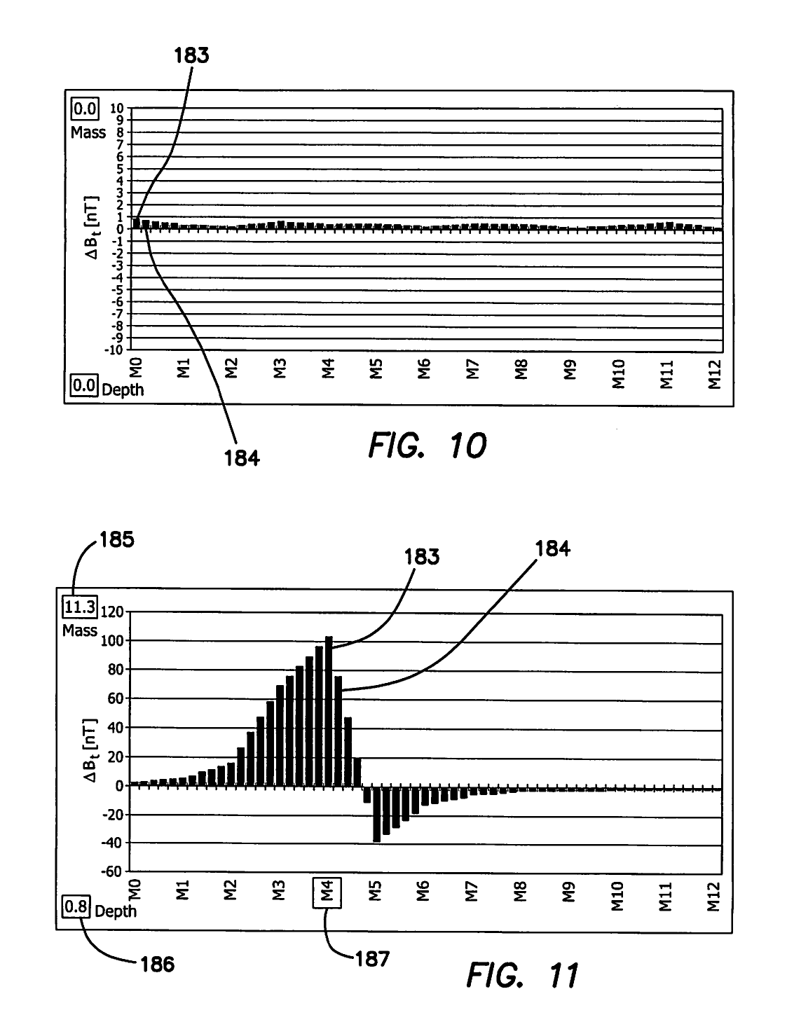

FIG. 10 depicts one example of a real time display. The display bars 183 indicate the normalized differential output of each sensor in 13 sensor array, M0 through M12 as shown along the abscissa. The bars 184 are interpolated. Note that the ordinate is scaled in ηT, which in practice auto scales depending on the largest sensor output. For this example, the array is not in close proximity to any object of interest, hence, the output of all sensors is near zero.

FIG. 11 depicts another example of a real time display. The bars 183 and bars 184 are as before, indicating the normalized differential output of each sensor, M0 through M12. In this case, the array has been presented with an 11.3 kg object, 0.8 meters directly under sensor number M4. Note that the object's apparent magnetic mass is indicated by box 185, its depth is indicated by box 186, and it location relative to the array is shown as the highlighted box 187.

Although the invention has been described in detail with reference to several embodiments, additional variations and modifications exist within the scope and spirit of the invention as described and defined in the following claims.

I claim:

1. A differential gradiometric magnetometer comprising:
an array of magnetic field sensors configured in a spaced arrangement; and
a support for maintaining said sensors in said spaced arrangement.

2. The magnetometer of claim 1 wherein said magnetic field sensors are linearly arranged.

3. The magnetometer of claim 2 wherein said magnetic field sensors are evenly spaced.

4. The magnetometer of claim 1 wherein the magnetic field sensors are coaxially or orthogonally arranged.

5. The magnetometer of claim 1 further comprising three or more magnetic field sensors.

6. The magnetometer of claim 1 further comprising operational computer software configured to analyze data acquired by said magnetic field sensors.

7. The magnetometer of claim 6 wherein said operational computer software is configured to nullify source noise from the magnetic field of the earth, external radio frequency transmissions and electromagnetic noise.

8. The magnetometer of claim 6 wherein said operational computer software is configured to collect and process differential and gradiometric data simultaneously.

9. The magnetometer of claim 1 wherein at least one magnetic field sensor is utilized as a magnetic field reference sensor.

10. The magnetometer of claim 9 further comprising operational computer software configured to identify one element in a set of sensor data closest to zero and configured to nominate one or more magnetic field sensors as reference sensors.

11. A method of using a magnetometer comprising:
positioning said magnetometer near an area or items to be investigated;
analyzing acquired data to determine one or more of the following: position, shape, size and mass of a located object; and
wherein said magnetometer comprises an array of magnetic field sensors configured in a spaced arrangement, and a support for maintaining said sensors in said spaced arrangement.

12. The method of claim 11 further comprising positioning said magnetometer statically such that items to be investigated may pass thereby.

13. The method of claim 11 further comprising passing said magnetometer over an area to be investigated.

14. The method of claim 11 further comprising normalizing all sensor outputs of said array of magnetic field sensors to a common datum reference.

15. The method of claim 11 further comprising subtracting output of each magnetic field sensor in said array from output of one or more reference magnetic field sensors in order to generate a set of differential scalar magnetic field measures wherein said differential measures are distributed over a length of said array and correlated to a position of said magnetic field sensors along said array.

16. The method of claim 11 further comprising nullifying source noise from the magnetic field of the earth.

17. The method of claim 11 further comprising nullifying external radio frequency transmission associated with environmental electromagnetic noise.

18. The method of claim 11 further comprising nullifying external radio frequency transmission associated with environmental electromagnetic noise.

19. The method of claim 11 further comprising normalizing magnetic field interference associated with stationary objects near said array.

20. The method of claim 11 further comprising subtracting output of each magnetic field sensor in said array from output of one or more other designated magnetic field sensors in order to generate a set of gradiometric vector magnetic field measures wherein said gradiometric measures are distributed over a length of said array and correlated to a position of said magnetic field sensors along said array.

21. The method of claim 11 further comprising collecting magnetic field data in a spatial domain.

22. The method of claim 11 further comprising collecting and processing differential and gradiometric magnetic field data simultaneously to determine the location, axial orientation, apparent magnetic mass and magnetic moment of a located object.

23. The method of claim 11 further comprising collecting and processing differential and gradiometric data simultaneously.

24. A differential gradiometric magnetometer system comprising:
a magnetometer comprising:
an array of magnetic field sensors configured in a spaced arrangement; and
a support for maintaining said sensors in said spaced arrangement; and
operational computer software configured to analyze data acquired by said magnetic field sensors.

25. The system of claim 24 wherein said operational computer software is further configured to normalize all sensor outputs of said array of magnetic field sensors to a common datum reference.

26. The system of claim 24 wherein said operational computer software is further configured to subtract output of each magnetic field sensor in said array from output of one or more reference magnetic field sensors in order to generate a set of differential scalar magnetic field measures wherein said differential measures are distributed over a length of said array and correlated to a position of said magnetic field sensors along said array.

27. The system of claim 24 wherein said operational computer software is further configured to nullify source noise from the magnetic field of the earth.

28. The system of claim 24 wherein said operational computer software is further configured to nullify external radio frequency transmission associated with environmental electromagnetic noise.

29. The system of claim 24 wherein said operational computer software is further configured to nullify external radio frequency transmission associated with environmental electromagnetic noise.

30. The system of claim 24 wherein said operational computer software is further configured to normalize magnetic field interference associated with stationary objects near said array.

31. The system of claim 24 wherein said operational computer software is further configured to subtract output of each magnetic field sensor in said array from output of one or more other designated magnetic field sensors in order to generate a set of gradiometric vector magnetic field measures wherein said gradiometric measures are distributed over a length of said array and correlated to a position of said magnetic field sensors along said array.

32. The system of claim 24 wherein said operational computer software is further configured to collect magnetic field data in a spatial domain.

33. The system of claim 24 wherein said operational computer software is further configured to collect and process differential and gradiometric magnetic field data simultaneously to determine the location, axial orientation, apparent magnetic mass and magnetic moment of a located object.
